(19) United States
(12) Patent Application Publication
(10) Pub. No.: US 2008/0064155 A1
(43) Pub. Date: Mar. 13, 2008

(54) Method for Producing a Multi-Stage Recess in a Layer Structure and a Field Effect Transistor with a Multi-Recessed Gate

(75) Inventors: Pierre M.M. Baudet, Yerres (FR); Andre Collet, Mennecy (FR); Sylvain Demichel, Montrouge (FR)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/573,913

(22) PCT Filed: Aug. 26, 2005
(86) PCT No.: PCT/IB05/52804

§ 371 Date: Feb. 19, 2007

(30) Foreign Application Priority Data
Aug. 31, 2004 (EP) 04300563.6

(51) Int. Cl. H01L 21/336; H01L 21/311

(52) U.S. Cl. 438/197; 438/694; 257/E21.249; 257/E21.409

(57) ABSTRACT

The method for forming a multi-stage recess in a layer structure comprises forming a photo-resist film atop a layer structure; a first step (49, 70) of etching the layer structure through an opening of the photo-resist film used as a mask, for forming a first stage of the recess; a step of widening the opening of the photo-resist film after the first etching step, for producing a widened opening of the photo-resist film, and a second step (58, 72) of etching the layer structure through the widened opening of the photo-resist film for forming a second stage of the multi-stage recess.

### FIELD OF THE INVENTION

The invention relates to a method for producing a multi-stage recess in a layer structure and a Field Effect Transistor with a multi-recessed gate manufactured using this method.

### BACKGROUND OF THE INVENTION

A multi-stage recess may be used in a semiconductor layer structure of a FET (Field Effect Transistor) to receive a gate electrode. Such a recess configuration improves the performance of the FET. A multi-stage recess includes at least two recesses of different widths at different depths called stages. The width of each stage becomes narrower as the stage is closer to the bottom of the recess.

A method for producing a transistor having a double-recessed gate is disclosed in U.S. Pat. No. 5,364,816 (Boos et al.). This method uses a dielectric layer as an intermediate layer between the upper semiconductor layer of the transistor's structure, and the gate-level photo-resist film, used as mask. The function of this intermediate layer is different from the function of a second dielectric layer that is further formed as final passivation layer. This intermediate layer has for an object to control the extension of the high-field region between the gate and the drain and to increase the breakdown potential of the transistor.

The method of U.S. Pat. No. 5,364,816 is particularly directed to a hetero-junction transistor, such as a HEMT. In HEMT manufacturing according to U.S. Pat. No. 5,364,816, the semiconductor channel in the vicinity of the gate stripe is recess-etched twice in order to lower the high field localized in the gate-drain region, which can sharply affect the breakdown voltage. The use of double-recessed channel alters the field profile at the drain edge of the gate and can result in an increase of the gate-drain and source-drain breakdown voltages and a decrease of the output conductance. By further controlling the extension of the high-field region between the gate and the drain, the maximum gain of the HFET can be improved. This control is performed by the formation of the double-recessed channel geometry, in which a dielectric layer is used as an intermediate layer between the semiconductor, and the gate-level photo-resist film that is used in the manufacturing process.

A multi-layer semiconductor structure with a hetero-junction is first formed to produce the HFET. The hetero-structure HFET differs from a homo-structure FET in that said HFET layer structure includes materials of different band-gaps, in order to obtain higher performance levels, which would otherwise be unobtainable. The composition and doping of each layer material used in the hetero-structure can be varied, resulting in that the HFETs have significantly improved performances at increasingly high frequencies. The hetero-structure of the FET of U.S. Pat. No. 5,364,816 comprises III-V materials. The substrate is made of semi-insulating InP. The hetero-junction is formed between a narrow band-gap channel layer of InGaAs and a wide band-gap layer of InAlAs. Atop the wide band-gap layer, is a n+ doped InGaAs called cap-layer.

Source and drain metallization is first formed on the cap-layer. Then a dielectric layer of Si₃N₄, which is the above-cited intermediate layer, is deposited at the surface of the cap-layer, and source and drain. A photo-resist layer is then formed on said dielectric layer.

Using the photo-resist layer as a mask, in a first step, the pattern of the gate is transferred into the dielectric intermediate layer with a technique to yield an aperture that is able to reproduce the aperture of the mask with fidelity. The method of U.S. Pat. No. 5,364,816 uses a technique of dry etching called RIE (Reactive Ion Etching), which produces etching with no undercut of the dielectric layer with respect to the gate pattern of the photo-resist layer, thus no enlargement of the dielectric layer aperture with respect to the photo-resist gate aperture. This dry etching technique produces an “anisotropic” etching, i. e. a vertical etching without lateral etching.

Then, in a second etching step, the cap-layer is etched through the dielectric layer aperture to form a first gate recess in the cap-layer, using any kind of chemical etching.

In a third etching step performed through the photo-resist aperture, the dielectric intermediate layer is intentionally undercut in the lateral direction, with respect to the photo-resist aperture, using a plasma etching technique. This produces an enlarged aperture of the dielectric layer.

In a fourth etching step, the cap-layer and the underlying channel layer are given a further chemical etch, as in the second etching step, through the enlarged aperture of the dielectric layer, in order to form a double-recess structure. This double recess structure has a recess in the channel layer and a laterally wider recess in the cap-layer.

Thereafter, a gate metal layer is deposited by thermal evaporation upon the structure as provided by the fourth etching step, and then the photo-resist layer is removed with acetone. This leaves the gate metal stripe self-aligned with the edge of the aperture of the former photo-resist layer. This gate is in contact with the channel layer in the deep recess.

U.S. Pat. No. 5,364,816 teaches that a double-recessed gate is favorable because the n+ cap-layer is intentionally set back from the gate, which achieves obtaining higher breakdown voltages because electric fields in the vicinity are reduced to relaxation in the field profile at the drain side of the gate.

The method of U.S. Pat. No. 5,364,816 further comprises deposition, immediately after gate deposition, of an upper silicon nitride layer, called passivation layer, and formation of an air-gap between the transistor's active layers and the gate bonding-pad.

The method of U.S. Pat. No. 5,364,816 permits of forming the double-recessed gate structure using a combination of etching steps in the photo-resist film, the intermediate dielectric layer, the cap-layer and the channel layer. U.S. Pat. No. 5,364,816 teaches that a conventional double-recess process generally requires two different photo-resist films, called first and second photo-resist films, instead of the intermediate dielectric layer used as a first photo-resist film and one photo-resist film used as second photo-resist film. U.S. Pat. No. 5,364,816 further teaches that the additional gate lithography step, due to the two different photo-resist films, makes the process more complicated and difficult to control. In U.S. Pat. No. 5,364,816, the intermediate dielectric layer is still present in the completed device.

### SUMMARY OF THE INVENTION

Unfortunately, the double-recess technique disclosed in U.S. Pat. No. 5,364,816 presents some drawbacks. Among them, a dry etching technique, which is carried out with RIE equipment, is required. Not only is the RIE equipment expansive, but the RIE technique presents limitations when InAlAs layers (or more generally layers with Indium content) have to be etched. RIE operation for such layers, which are often present in the high performance transistors cited above, is only efficient at high temperature in order to obtain volatile species. These high temperatures are extremely detrimental to the cited layers, especially the layers with Indium content. In addition, the RIE dry etching technique may cause severe damages to the very thin active layers used in said high performance transistors. Moreover, RIE may affect the integrity of a supplementary multilayer resist system that is further used to define the final gate electrodes, in particular for sub 0.1 μm gates and mushroom-shaped gates.

According to the invention, instead of acting on the etching mechanism, the proposed method has steps to act on the dimension of the gate foot defined in the photo-resist film specifically used for forming the double-recess structure. Said photo-resist film is a single photo-resist film for forming a simple gate (no mushroom). Said photo-resist film is the first photo-resist film of a multi-resist system used for forming mushroom-shaped gates.

Accordingly, an object of the invention is to provide a method for forming a semiconductor multi-recess structure, which multi-recess structure is achieved without intermediate dielectric layer, however using a single photo-resist film, so that the completed structure has no remaining intermediate dielectric layer, such as the one present in the HMET disclosed in U.S. Pat. No. 5,364,816, and so that the method of the invention is devoid of the complexity due to the use of two photo-resist films.

According to the invention, said method comprises:

a first step of etching the semiconductor layer structure for forming a first stage of the multi-stage recess through an opening of a photo-resist film,

a step of widening said opening of the photo-resist film after the first etching step, for producing a widened opening of the photo-resist film, and

a second step of etching the semiconductor layer structure for forming a second stage of the multi-stage recess through the widened opening of the photo-resist film.

In the above method, the photo-resist film being used as a mask, the opening of the photo-resist film is used to form the deep recess; and then, said opening is widened between the first and second etching steps to form an enlarged opening that is used to produce the shallow recess. As a result, the two stages of different widths are formed through said opening and said widened opening of this photo-resist film.

An advantage of the method of the invention is that a single photo-resist film is formed, and a single photolithography step is used for forming successively the two openings of different widths in this single photo-resist film, instead of using a photo-resist film having a first aperture and a dielectric layer having a second wider aperture, according to the method proposed in the cited prior art, or instead of using two different photo-resist films with two different apertures as known to those skilled in the art.

The features of claims 2 through 4 have the advantages of reducing manufacturing costs. The features of claim 5 have the advantages of accurately controlling the location of the bottom of the multi-stage recess. The features of claim 6 permit of increasing the breakdown voltage of a Field Effect Transistor.

So, another very important advantage is that this method may be carried out using wet etching techniques instead of expensive dry etching techniques.

Because of the anisotropy of the RIE etching steps of the cited prior art, which anisotropy permits of only etching in a vertical direction, during manufacture of a double recess, the series resistance of the access regions (outside the gate) are detrimental compared to the series resistance of the access regions obtained during manufacture of a double recess using wet etching steps, because wet etching performs a lateral etching together with the vertical etching (isotropy of the wet etching). As a result, due to the important thickness that is required for the cap layer, the surface influence is reduced, which is also important for not observing additional parasitic effect such as kink-effect.

Hence, the method of the invention is preferably carried out using wet etching techniques instead of RIE, which avoids damaging the fragile layers and the thin layers of the semiconductor structure.

Coupling the advantage of the use of a single photo-resist layer and a single photolithography step with the advantage of the use of wet etching now provides a very interesting method of manufacturing integrated circuits. Added to the former and latter advantages, another important advantage is that this method permits of reducing the gate length of transistors to the range of sub 0.1 μm, while possibly realizing mushroom-shaped gates, or buried gates. This advantage renders this method still more attractive.

Besides, the HEMT exemplified in U.S. Pat. No. 5,364,816 shows a cap layer having a thickness of about 10 nm (0.01 μm). This thickness is very small and detrimental to quality of ohmic contacts in term of low resistance value and long-term reliability. Instead, according to the invention, in the application to high mobility transistors, the cap layer is 20 nm thick or more, which improves the quality of ohmic contacts.

The features of claim 8 allow of manufacturing a lower stage of a multi-stage recess having a width that is close to the dimension of the foot of the gate electrode, for example close to the gate length.

The method of the invention permits of manufacturing a semiconductor device comprising an integrated active element, of the kind operating at high speed, low noise and/or high power III-V element, such as the kind operating at frequencies as high as 200 GHz or above, particularly such as a device comprising with III-V HMET, or III-V MHEMT or PHEMT element.

The method of the invention permits of minimizing the length of the transistor's gate. The method of the invention permits of manufacturing a semiconductor device comprising an integrated active element, of the kind cited above, with a double-recessed mushroom-shaped gate in the range of sub 0.1 μm. Alternately, the method of the invention permits of manufacturing a semiconductor device comprising an integrated active element, of the kind cited above, with a double-recessed buried gate.

Also, for manufacturing such high performance devices as cited, a highly thick cap layer is needed, of about 0.02 μm, for improving the ohmic contacts and the device long-term reliability. This thickness is greater than the thickness used in the cited prior art. Besides, such a thickness of about 0.02 μm or more is most convenient for manufacturing a multi-recessed gate according to the method of the invention.

These and other aspects of the invention will be apparent from the following description, drawings and claims.

### BRIEF DESCRIPTION OF THE DRAWINGS

FIG. 1A and FIG. 1B are schematic diagrams of an electronic device having a double-stage recess;

FIG. 2 is a flowchart of a method for manufacturing the double-stage recess of FIG. 1A;

FIG. 3A and FIG. 3B are schematic diagrams of the device of FIG. 1A during specific steps of the manufacturing method of FIG. 2;

FIG. 4 is a flowchart of another method for manufacturing the double-stage recess of FIG. 1B; and

FIG. 5A and FIG. 5B are schematic diagrams of a device during specific steps of the method of FIG. 4.

### DESCRIPTION OF THE PREFERRED EMBODIMENTS

The present invention relates to a method for producing a multi-stage recess in a semiconductor structure and to a method for manufacturing an electronic element with a multi-stage recess, for receiving a control electrode such as a gate electrode.

Only for illustration purposes, this electronic element will be described in the special case of a FET manufactured using III-V semiconductor materials formed from a multi-layer structure. As an example, III-V semiconductor materials may comprise gallium arsenide compounds.

The device may have a multi-stage recess in a sub-10 μm range in width. Preferably, the device may have a multi-stage recess in a sub-0.1 μm range in width. The width of the deepest level of the recess is parallel to the length of the gate electrode. The multi-layer structure of gallium arsenide compounds may comprise InAlAs layers,(or more generally layers with Indium content).

The method of the invention is also applicable to manufacturing a hetero-junction transistor such as a HEMT (High Electron Mobility Transistor).

For manufacturing a high performance HEMT, the use of a double recessed channel and a simple gate may be carried out. For manufacturing a high performance MHEMT or PHEMT, the use of both a double recessed channel and a mushroom gate are most favorable. These devices favorably comprise sub 0.1 μm gates, whose realization is performed using sub 0.1 μm gate photolithography. Alternately, with a double-recessed channel, the gate may be of the kind called buried gate.

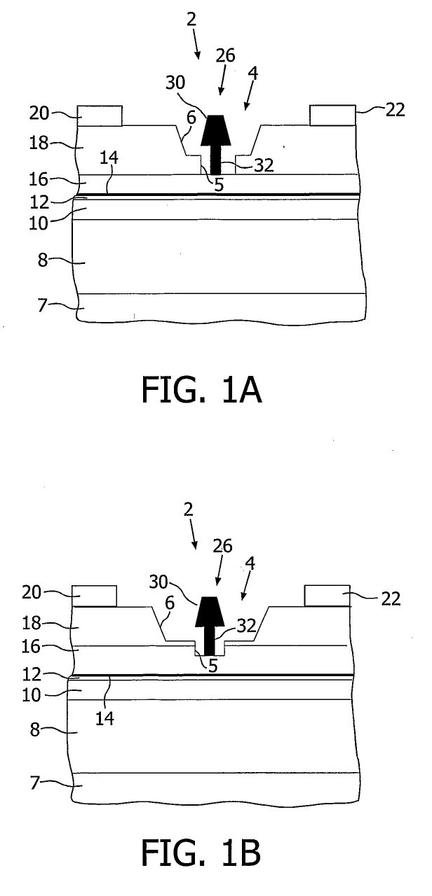

The invention is applicable for manufacturing any high speed, low noise and/or high power III-V devices such as III-V MHEMT or PHEMT discrete devices or III-V PHEMT or MHEMT based Integrated Circuits operating at frequencies as high as 200 GHz or above. In particular, the method of the invention is applicable to manufacturing a metamorphic or pseudomorphic high electron mobility transistor having a multi-stage recess for receiving a sub-0.1 μm gate electrode. As an example, FIG. 1 illustrates a MHEMT (Metamorphic High Electron Mobility Transistor) 2 having a double-stage recess 4. The recess 4 has a lower stage 5 and an upper stage 6. The width of stage 5 is smaller than the width of stage 6. A horizontal section discriminates stage 5 from stage 6. FIG. 1 shows only the details necessary to understand the invention. The transistor 2 has a multi-semiconductor layer structure, each of these layers being illustrated as a horizontal layer.

The multi-semiconductor layer structure includes, starting from the bottom of the structure:

a substrate 7,

a buffer layer 8 to reduce the influence of substrate 7 on the electrical characteristic of the transistor,

a channel layer 10,

a spacer layer 12,

a thin supply layer 14, which is shown as a thickened line,

a Schottky layer 16, and

a cap layer 18.

The above-cited transistors may be used to manufacture a semiconductor device such as a Monolithic Microwave Integrated Circuit (MMIC). Such a device may include a HEMT, as shown in FIG. 1A and FIG. 1B, which comprises, stacked on a semiconductor substrate 7, at least a semiconductor active layer 16.

Referring to FIG. 1A and FIG. 1B, in a preferred embodiment, the active layer 16 is covered by a semiconductor cap-layer 18 of lower resistivity. The field effect transistor also comprises, on the semiconductor layers, a source electrode 20 and a drain electrode 22 between which a channel is realized by means of a double-level recess. This double-level recess comprises a deeper and narrower central recess 5 and a shallower and larger peripheral recess 6. This transistor further comprises a gate electrode 26, which is in contact with the active layer 16 in the central recess 5.

In FIG. 1A and FIG. 1B, the transistor is of the high electron mobility type (HEMT) and comprises, in the stacked arrangement for forming the active layer realized on the substrate 7, at least two layers having different electron affinities so as to form a hetero-junction comprising a lower active layer 10 made of a first material having a first forbidden bandwidth and an upper active layer 16 made of a second material having a greater forbidden bandwidth and forming a hetero-structure with the first layer 10, with interface 14.

In FIG. 1A and FIG. 1B, for forming the structure of the HEMT, advantageously a cap-layer 18, strongly n⁺⁺ doped, is present. This cap-layer has a function of reducing the source and drain resistance of the transistor by increasing the conduction of the semiconductor material in the regions situated below the ohmic source and drain contacts 20, 22, and a function of forming a spatial separation between the channel region and the regions lying below the ohmic source and drain contacts 20, 22, which are mechanically and electrically disturbed during the fusion of the material for constituting said ohmic contacts 20 and 22 owing to the fact that said material is an eutectic material for forming a metal-semiconductor alloy. The recesses 5, 6 are realized in the cap-layer 18. According to the invention, the cap layer has favorably a thickness of 20 nm (0.02 μm) or more.

The HEMT structure also comprises a metal pad for the gate 26, which is directly deposited on the material of the upper active layer 16 so as to form a Schottky barrier which is present at a very exact distance away from the bottom of the active layer 16, i.e. from the interface 14 of the hetero-structure. This distance represents the effective thickness of the upper active layer 16 and governs the operation of the transistor, i.e. its pinch-off voltage, whereby an enhancement-type or on the contrary a depletion-type transistor is formed.

This HEMT not only shows an improved saturation voltage, but also an increased breakdown voltage as well as low access resistances. The breakdown voltage value depends on the distance separating the edge of the gate metallization 26 from the edges of the recesses 5, 6. In the transistor described above, the portion of the active layer 16 lying below the central deeper recess is preferably not intentionally doped.

An advantageous process for realizing a field effect transistor having a double-level recessed gate, and source and drain electrode contacts, as described above, may include several steps illustrated by FIG. 1A, FIG. 1B, FIG. 3A, FIG. 3B and FIG. 5A, 5B.

The method of the present invention is valuable for all type of transistors and not only for hetero-junction transistors.

According to FIG. 1A and FIG. 1B, for forming a field effect transistor, the process may comprise the formation of a substrate 7 from semi-insulating gallium arsenide (GaAs) and the formation of an active layer 16 of indium aluminum arsenide (InAlAs), called Schottky layer.

In a preferred embodiment, for forming a transistor HEMT, the process may comprise the formation of:

a substrate 7 from semi-insulating gallium arsenide;

a buffer layer 8 of indium aluminum arsenic (InAlAs);

a channel layer 10 of gallium-indium arsenide (GaInAs), having an indium concentration of the order of 20 to 80%, and having a thickness lying between about 10 and 30 nm;

a spacer layer 12 of 2 to 5 nm;

a doped plane 14, forming the thin supply layer;

a Schottky layer 16 of indium-aluminum arsenide (InAlAs), having a thickness of 5 to 30 nm, which defines the threshold voltage;

a cap-layer 18 of indium gallium arsenide (GaInAs), strongly n⁺⁺ doped, and having a thickness lying of about 20 nm or more.

All the layers are not intentionally doped, to the exception of the plane 14 and the cap layer 18.

The gallium-indium arsenide (GaInAs) channel layer 10 has a given forbidden bandwidth, while the Schottky layer 16 of indium-aluminum arsenide (InAlAs) has a greater forbidden bandwidth. The HEMT according to this arrangement is called pseudomorphic and has an improved performance because the difference between the forbidden bandwidths of the materials is greater. A two-dimensional electron gas establishes itself in a HEMT at the interface 14 of the layers of different forbidden bandwidths.

The stack of layers of semiconductor materials is completed for example by means of epitaxial growth, for which favorably a technique known to those skilled in the art is used such as molecular beam epitaxy or organo-metallic vapor phase deposition.

It is advantageous that the next steps are those of forming the ohmic contacts of source and drain. These steps are conventional, are well known to those skilled in the art and thus, are not described thereafter. On top of cap layer 18, a source metallization 20 and a drain metallization 22 are formed on the left and right sides of the recess 4, respectively.

The transistor 2 further includes an electrode gate 26 that is vertically disposed at the centre of recess 4. This electrode 26 advantageously shows a mushroom shape, having an enlarged head 30 connected to a foot 32, which has a predetermined width smaller than the head width. In FIG. 1, foot 32 is illustrated as a thin vertical rod. The foot 32 is positioned at the centre of stage 5 and its free end contacts the Schottky layer 16. The large head of the mushroom-shaped gate decreases the resistance of the gate electrode and allows for better performance of transistor 2.

Typically, the method of the invention permits of easily manufacturing, with reduced cost and with uniform, repetitive accuracy, transistors whose width of foot 22 is less than 0.1 μm. Such transistors show greatly improved performances. This method provides extremely great density of integration for forming integrated circuits.

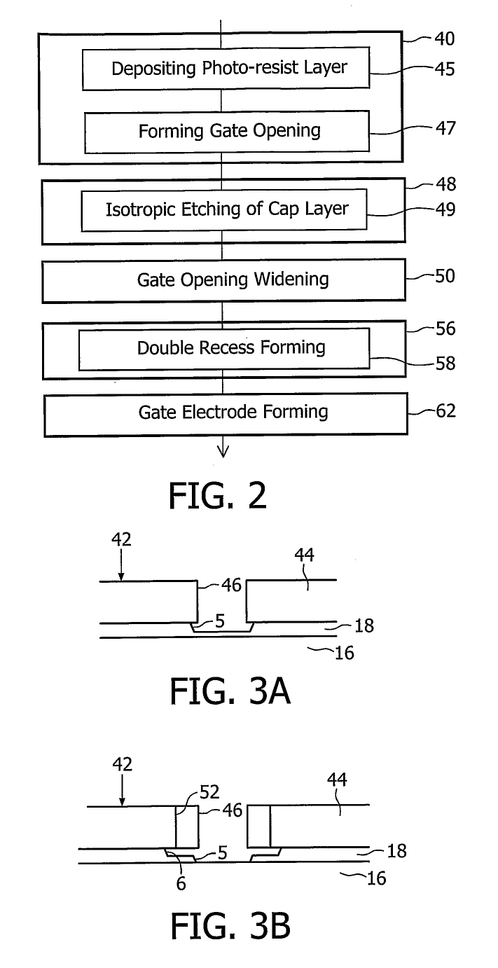

A method for manufacturing transistor 2 will now be explained with reference to FIG. 1A, FIG. 2, FIG. 3A and FIG. 3B. Hereinafter, only the steps necessary to understand the invention are described in details. The other steps for manufacturing transistor 2 are conventional and not described.

Regarding the manufacture of the double-recessed channel, according to the invention, the method comprises the following steps.

Once the multi-semiconductor layer structure of FIG. 1A has been built, a photo-resist pattern 42, as illustrated by FIG. 3A, is formed on top of the cap layer 18 in a step 40. In FIG. 3a and 3b, only layers 16 and 18 have been represented. A photo-resist film 44 is first deposited on the cap layer 18 during an operation 45. Then a gate opening 46 is delineated in film 44 by exposure and development, during an operation 47. This forms the photoresist pattern 42. For example, electron-beam or other exposure means may be used for the exposure of the photoresist film.

The width of the opening 46 is favorably thinner than the width that is wanted for the gate length, represented by foot 32, in order to compensate for the widening of stage 5 due to wet etching. Thus, the widening of stage 5 is well controlled. This allows for the formation of a first stage 5 having a width that is equal to or only slightly greater than the width of foot 32, called gate length, even when using wet etching techniques. Hence, as a result, this method can be used for sub-0.1 μm gate electrodes.

For example, the width of opening 46 may be equal to or less than 50 nm (0.05 μm). Using the method of the invention, the width of the opening 46 can be drastically reduced with respect to the prior art. Widths of about 20 nm (0.02 μm) can be obtained, which provides important improvements of the integrated circuits in microwave applications.

Once the resist pattern 42 has been formed, stage 5 is formed in the cap layer 18 in a step 48. To do so, during an operation 49, a first wet etching is carried out, through the opening 46, using the resist pattern 42 as a mask. As a result, the first stage 5 of the double recess 4 is realized in the cap layer 18. The wet etching operation 49 etches the cap layer 18 in both vertical and horizontal directions, of about equal quantity. This wet etching technique, having the same action in all directions, is called isotropic. Therefore, as illustrated in FIG. 3A, the width of stage 5 is larger than the width of the opening 46 at the end of operation 49, as illustrated by FIG. 3A.

Thereafter, in a step 50, the width of the opening 46 of the photo-resist layer is widened in the horizontal direction, in order to provide the widened opening 52. This step is realized by means of an over-development of photo-resist film 44. The over-development operation is carried out in a similar way as a conventional development operation, to perform a controlled enlargement of the initial opening 46 formed during the first development.

Hence, this new development operation is not preceded by a new exposure. For example, the over-development operation is controlled in order to increase the width of opening 46 by 0.01 μm. A widened opening 52 resulting from step 50 is illustrated in FIG. 3b. In FIG. 3b, the former opening 46 is shown as a dotted line. Subsequently, in a step 56, the stage 6 of the double recess 4 is formed in cap layer 18 through the widened opening 52. This is done, during an operation 58, by carrying out a selective wet etching of cap layer 18 through the widened opening 52 of the mask 42. During the wet etching operation 58, stage 5 is also widened in the horizontal direction and deepened in the vertical direction. Since selective etching is carried out, the deepening of stage 5 automatically stops when Schottky layer material 16 is reached.

As a result, the double-recess 4 is only formed in the cap layer 18.

Then, in a step 62, a gate electrode 26 is formed in the double recess 4. In step 62, the mushroom shape of gate electrode 26 is obtained by an operation of depositing a metal gate electrode and lifting off the gate material around the gate pad, by elimination of further photo-resist layers, which are specifically used to define the gate shape, for example. Typically, the operation of gate forming may be achieved by using a multi-layer resist system, such as a bi-layer, tri-layer or even quadri-layer resist system. In such a case, the photo-resist film 44 shown in FIG. 3A and 3B and previously described as “single photo-resist layer 44” according to the invention, is now the lowest photo-resist layer of the multi-layer resist system. The photoresist layers for defining the mushroom-shaped gate are then supplementary layers previously formed atop layer 44.

According to the invention, the formation of the multi-recess uses only one photo-resist layer and one photolithography step (exposure step).

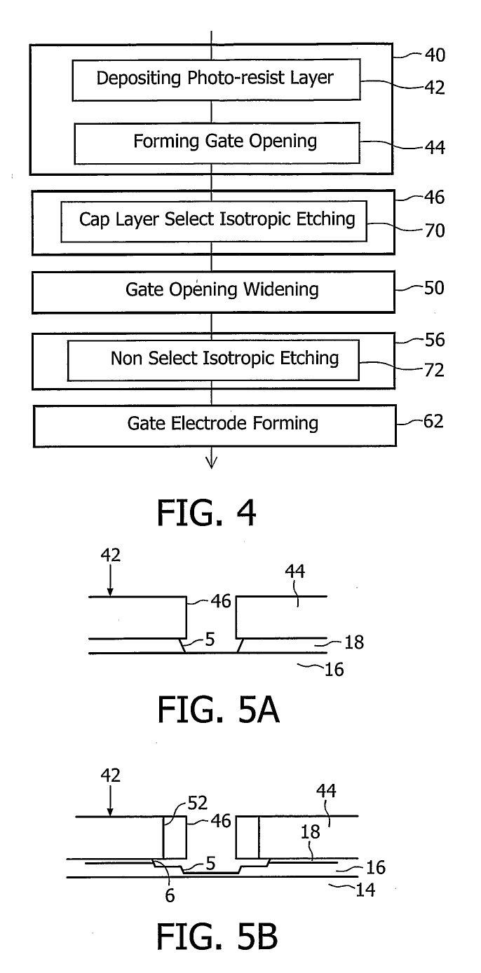

FIG. 4, FIG. 1B, FIG. 5A, and FIG. 5B illustrate another embodiment of a method for manufacturing a FET. In these figures, the elements already described in FIG. 1A, FIG. 2, FIG. 3A and FIG. 3B have the same references. This method is identical to the method of FIG. 2 with the exception that operations 49 and 58 are replaced by operations 70 and 72.

The operation 70 is a selective wet etching in that the etching of the cap layer 18 automatically stops once the bottom of stage 5 reaches the Schottky layer material 16, as illustrated in FIG. 5a.

The operation 72 is a non-selective wet etching in that, at the end of step 56, the bottom of stage 5 is located in layer 17 but does not contact layer 14, as illustrated in FIG. 5B. Such a configuration of the double-stage recess permits of increasing the breakdown voltage of the manufactured FET.

The methods of FIG. 2 and 4 are effective to form a double-stage recess using only the lowest photo-resist film 44 of the system of multi-layer of photo-resist films that may be used for the purpose of constructing the transistor gate. As a result, the figures illustrating these methods illustrate only the one operation of depositing the photo-resist film 44 on top of the cap layer 18, for forming the double recess. Hence, these methods do not require the formation of an extra mask layer like an intermediate dielectric layer, or like a second photo-resist layer, for example.

These methods are also cost saving since they do not require the use of expensive techniques to transfer the pattern of the mask opening within a semiconductor layer. For example, steps involving reactive ion etching are not necessary even for transistor having sub-0.1 μm gate electrode.

Regarding the manufacture of a sub 0.1 μm gate itself, the gate photolithography generally requires the use of a multi-layer resist system (bi-layer, trilayer or even a quadri-layer system) in which the above cited “single” photo-resist layer is in a position of “first layer” or “lowest layer”. This kind of gate photolithography may be performed using electron-beam technology to expose said multilayer resist system. These multilayer systems are well known to those skilled in the art, having been extensively reported in the literature related to the fabrication of high performance millimeter wave devices with mushroom-shaped gates. Generally, in a bi-layer resist system, the lower resist defines the gate foot, which is also the gate length, and the upper layer defines the top of the mushroom. Additional resists help to achieve a good metal lift-off thanks to a specific resist profile.

In another embodiment, which is not illustrated by a figure, the overdevelopment may be greater than in the above-described embodiment so that the shallow recess may be widened. Then the gate metallization may cover the deep recess and a part of the shallow recess. So, the gate electrode extends over the entire deep recess and beyond said deep recess. The gate length is greater than the width of the deep recess parallel to the gate length. This type of gate is called a “buried gate”. This provides increased saturation voltage of the transistor and permits of better controlling the threshold voltage. This embodiment is particularly useful for enhancement transistors.

Many additional embodiments are possible. For example, the widening step and the wet etching step through the widened opening in the photo-resist film used as a mask may be repeated several times in order to create a multi-stage recess having three, four or more stages. The widening step can be achieved using a plasma descumming bath instead of an over-development operation.

The foregoing method has been described in the special case of a gate electrode having a mushroom shape. However, the method also applies to electrode gates having other shapes, i.e., stick or rod like shapes.

Finally, the methods have been described for manufacturing a FET. However, the teaching herein disclosed applies to every microelectronic device having a multi-stage recess.

1. A method of forming a multi-stage recess in a layer structure comprising:
forming a photo-resist film atop a layer structure;
a first step (49, 70) of etching the layer structure through an opening of the photo-resist film used as a mask, for forming a first stage of the recess;
a step of widening the opening of the photo-resist film after the first etching step, for producing a widened opening of the photo-resist film, and
a second step (58, 72) of etching the layer structure through the widened opening of the photo-resist film for forming a second stage of the multi-stage recess.

2. The method of claim 1, wherein the first and second etching steps are wet etching steps.

3. The method according to claim 1, wherein the widening step is achieved using an over development of the photo-resist film.

4. The method according to claim 1, wherein the widening step is achieved using a plasma descumming bath.

5. The method according to claim 1, for forming a multi-stage recess in a semiconductor layer structure having a top semiconductor layer superimposed on a lower semiconductor layer, wherein the second etching step is a selective etching step (58) to only form the multi-stage recess in the top layer.

6. The method according to claim 1, for forming a multi-stage recess in a semiconductor layer structure comprising a top semiconductor layer superimposed on a lower semiconductor layer, wherein the second etching step is a non-selective etching step (72) to form the multi-stage recess in the top and the lower layers.

7. A method for manufacturing a Field Effect Transistor (FET) having a multi-stage recess, wherein the multi-stage recess is formed by using a method according to claim 1.

8. The method of claim 7 for manufacturing a FET having a gate electrode, a foot of the gate electrode being received in the multi-stage recess, wherein the second etching step is a wet etching step and wherein, before the first etching step, the method comprises the steps of:
depositing the photo-resist film on top of the semiconductor layer structure, and
forming the opening in the photo-resist film that is used as a mask during the first etching step, wherein the width of the opening is smaller than the width of the gate electrode foot.

9. A method of manufacturing a metamorphic or pseudomorphic high electron mobility transistor having a multi-stage recess for receiving a sub-0.1 μm gate electrode, wherein the multi-stage recess is formed using a method according to claim 7.
